(19) United States
(12) Patent Application Publication
(10) Pub. No.: US 2021/0066052 A1
(43) Pub. Date: Mar. 4, 2021

(54) PLASMA PROCESSING APPARATUS

(71) Applicant: Kioxia Corporation, Minato-ku (JP)

(72) Inventor: Kazuya EMURA, Ama (JP)

(73) Assignee: Kioxia Corporation, Minato-ku (JP)

(21) Appl. No.: 16/817,686

(22) Filed: Mar. 13, 2020

(30) Foreign Application Priority Data
Sep. 2, 2019 (JP) 2019-159787

(51) Int. Cl. H01J 37/32

(52) U.S. Cl. CPC H01J 37/32642; H01J 37/32532; H01L 21/67069; H01J 2237/20235; H01J 2237/3341; H01J 37/32715

(57) ABSTRACT

According to one embodiment, a plasma processing apparatus includes a processing container processing a substrate, a power supply supplying an electric power into the processing container to generate plasma, an upper electrode arranged inside the processing container, a substrate mounting table including a lower electrode opposed to the upper electrode, and placing the substrate thereon, an edge ring arranged at an outer peripheral portion of the substrate mounting table to surround an periphery of the substrate, and a drive mechanism driving at least part of the edge ring up and down. The edge ring includes a lower ring mounted on the outer peripheral portion of the substrate mounting table, an upper ring mounted on the lower ring to be movable up and down by the drive mechanism, and an auxiliary ring arranged at a lower surface of the upper ring to be movable up and down together with the upper ring, and including a surface facing a side to be opened to an inside of the processing container.

### CROSS-REFERENCE TO RELATED APPLICATIONS

This application is based upon and claims the benefit of priority from Japanese Patent Application No. 2019-159787, filed on Sep. 2, 2019; the entire contents of which are incorporated herein by reference.

### FIELD

An embodiment of the present invention described herein relates generally to a plasma processing apparatus.

### BACKGROUND

In a plasma processing apparatus for processing a substrate, members in the processing container are worn out by plasma. When an edge ring arranged around the substrate is worn out, the plasma sheath is distorted and thereby causes fluctuations of the process characteristics.

### BRIEF DESCRIPTION OF THE DRAWINGS

FIG. 1 is a sectional view schematically illustrating a configuration example of a plasma processing apparatus according to an embodiment;

FIG. 2 is a sectional view on one side of an edge ring according to the embodiment;

FIGS. 3A and 3B are schematic views each illustrating a state where the edge ring according to the embodiment is used in the plasma processing apparatus;

FIGS. 4A and 4B are schematic views each illustrating a state where an edge ring of a plasma processing apparatus according to a comparative example is used;

FIG. 5 is a schematic view illustrating a state where an edge ring is used in a plasma processing apparatus according to a modification 1 of the embodiment; and

FIG. 6 is a schematic view illustrating a state where an edge ring is used in a plasma processing apparatus according to a modification 2 of the embodiment.

### DETAILED DESCRIPTION

In general, according to one embodiment, a plasma processing apparatus includes a processing container processing a substrate, a power supply supplying an electric power into the processing container to generate plasma, an upper electrode arranged inside the processing container, a substrate mounting table including a lower electrode opposed to the upper electrode, and placing the substrate thereon, an edge ring arranged at an outer peripheral portion of the substrate mounting table to surround an periphery of the substrate, and a drive mechanism driving at least part of the edge ring up and down. The edge ring includes a lower ring mounted on the outer peripheral portion of the substrate mounting table, an upper ring mounted on the lower ring to be movable up and down by the drive mechanism, and an auxiliary ring arranged at a lower surface of the upper ring to be movable up and down together with the upper ring, and including a surface facing a side to be opened to an inside of the processing container.

The present invention will be explained below in detail with reference to the accompanying drawings. The present invention is not limited to the following embodiment. The constituent elements in the following embodiment encompass those which can be easily assumed by a person skilled in the art, or which are substantially equivalent thereto.

(Configuration Example of Plasma Processing Apparatus)

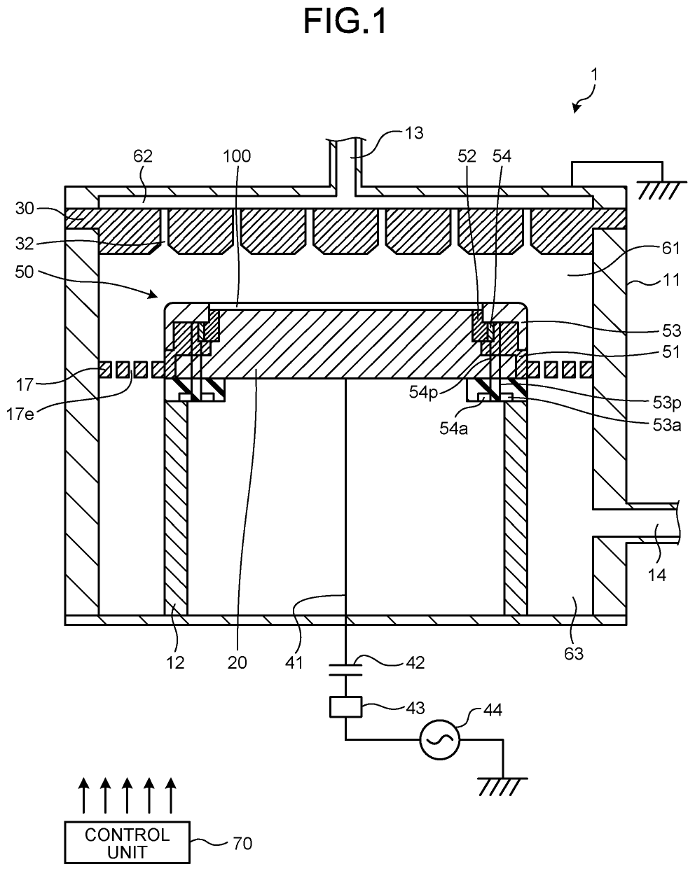

FIG. 1 is a sectional view schematically illustrating a configuration example of a plasma processing apparatus according to an embodiment. For example, the plasma processing apparatus 1 is configured as a Reactive Ion Etching (RIE) apparatus for performing a plasma etching process on a wafer 100 serving as a substrate.

As illustrated in FIG. 1, the plasma processing apparatus 1 includes a chamber 11 configured to be airtight and serving as processing container, which is made of aluminum, for example.

The chamber 11 is provided with a gas supply port 13 near the upper side. The gas supply port 13 is connected to a gas supply unit (not illustrated) through a piping line, to be supplied with a processing gas used for a plasma process.

A showerhead 30 functioning as an upper electrode is provided near the upper side of the chamber 11 and below the gas supply port 13. The showerhead 30 is provided with a plurality of gas flow passages 32 that penetrate in the plate thickness direction. The processing gas supplied from the gas supply port 13 is introduced into the chamber 11 through the gas flow passages 32.

A wafer stage 20 serving as a substrate mounting table is arranged below the showerhead 30 and opposed to the showerhead 30. The wafer stage 20 includes an electrode built therein. The wafer stage 20 is configured to support the wafer 100 treated as a processing object in a horizontal state, and to function as a lower electrode. The wafer stage 20 may be provided with an electrostatic chuck that attracts and holds the wafer 100 by an electrostatic force.

The wafer stage 20 is supported on a support part 12 that has a cylindrical shape and projects vertically upward from a bottom wall near the center of the chamber 11. The support part 12 supports the wafer stage 20 such that the wafer stage 20 is opposed to the showerhead 30 in parallel. Further, the support part 12 supports the wafer stage 20 such that the wafer stage 20 is positioned near the center of the chamber 11 and separated from the showerhead 30 by a predetermined distance. With the structure described above, the showerhead 30 and the wafer stage 20 form a pair of parallel plate electrodes.

The wafer stage 20 is connected to a power supply line 41 for supplying a high frequency power. The power supply line 41 is connected to a blocking capacitor 42, a matching device 43, and a high frequency power supply 44. At the time of a plasma process, the high frequency power supply 44 supplies a high frequency power having a predetermined frequency to the wafer stage 20.

An edge ring 50 is arranged at the outer circumferential side of the wafer stage 20 to cover the side surface of the wafer stage 20 and the bottom surface of the peripheral portion of the wafer stage 20. The edge ring 50 adjusts the electric field during etching performed on the wafer 100 so that the electric field is not to be deflected at the peripheral portion of the wafer 100 with respect to the vertical direction, which is perpendicular to the wafer surface.

For example, the edge ring 50 is composed of a plurality of members, which are a lower ring 51, an intermediate ring 52, an upper ring 53, and an auxiliary ring 54. Each of the members is made of, for example, quartz, silicon, silicon carbide, ceramic, or the like. These members may be made of materials different from each other. The configuration of each of these members will be described later in detail.

Pins 53p and pins 54p are provided below the edge ring 50. Here, the pins 53p penetrate through the peripheral portion of the wafer stage 20 and come into contact with the lower surface of the upper ring 53. The pins 54p penetrates through the peripheral portion of the wafer stage 20 and come into contact with the lower surface of the auxiliary ring 54.

Each of the pins 53p is connected to a drive unit 53a, such as an actuator including an encoder. The upper ring 53 is arranged to be moved up and down when the pins 53p are driven up and down by the drive units 53a. Each of the pins 54p is connected to a drive unit 54a, such as an actuator including an encoder. The auxiliary ring 54 is arranged to be moved up and down when the pins 54p are driven up and down by the drive units 54a.

Here, the upper ring 53 is supported by the plurality of pins 53p, which are arranged at regular intervals in the circumferential direction of the upper ring 53. Further, the auxiliary ring 54 is supported by the plurality of pins 54p, which are arranged at regular intervals in the circumferential direction of the auxiliary ring 54. It suffices that each group of the pins 53p and the pins 54p is composed of three or more pins. Here, each of the pins 53p and 54p is provided with the drive unit 53a or 54a.

A drive mechanism is formed mainly of three or more pairs of the pins 53p and 54p and three or more pairs of the drive units 53a and 54a corresponding to the pairs of the pins.

A baffle plate 17 is provided between the edge ring 50 and the sidewall of the chamber 11. The baffle plate 17 includes a plurality of gas exhaust holes 17e that penetrate in the plate thickness direction.

The chamber 11 is provided with a gas exhaust port 14 below the baffle plate 17. The gas exhaust port 14 is connected to a vacuum pump (not illustrated) serving as exhaust means through a piping line.

The area partitioned by the wafer stage 20, the baffle plate 17, and the showerhead 30 in the chamber 11 serves as a plasma processing room 61. The area partitioned by the showerhead 30 on the upper side in the chamber 11 serves as a gas supply room 62. The area partitioned by the wafer stage 20 and the baffle plate 17 on the lower side in the chamber 11 serves as a gas exhaust room 63.

When a plasma process is to be performed on the wafer 100, the wafer 100 treated as a processing object is placed onto the wafer stage 20. Further, the inside of the chamber 11 is vacuum exhausted by the vacuum pump (not illustrated) connected to the gas exhaust port 14. When the inside of the chamber 11 reaches a predetermined pressure, a processing gas is supplied from the gas supply unit (not illustrated) into the gas supply room 62, and is supplied through the gas flow passages 32 of the showerhead 30 into the plasma processing room 61. In a state where the showerhead 30 serving as the upper electrode is grounded, a high frequency voltage is applied to the wafer stage 20 serving as the lower electrode, and plasma is thereby generated in the plasma processing room 61. Due to the high frequency voltage, a self bias is applied on the lower electrode side, and a potential gradient is generated between the plasma and the wafer 100. Thus, ions in the plasma are accelerated toward the wafer stage 20, and an anisotropic etching process is thereby performed.

A control unit 70 is configured to control respective components of the process processing apparatus 1, such as the wafer stage 20, the high frequency power supply 44, the drive units 53a and 54a, the gas supply unit, and the vacuum pump, so as to conduct the plasma process described above.

(Configuration Example of Edge Ring)

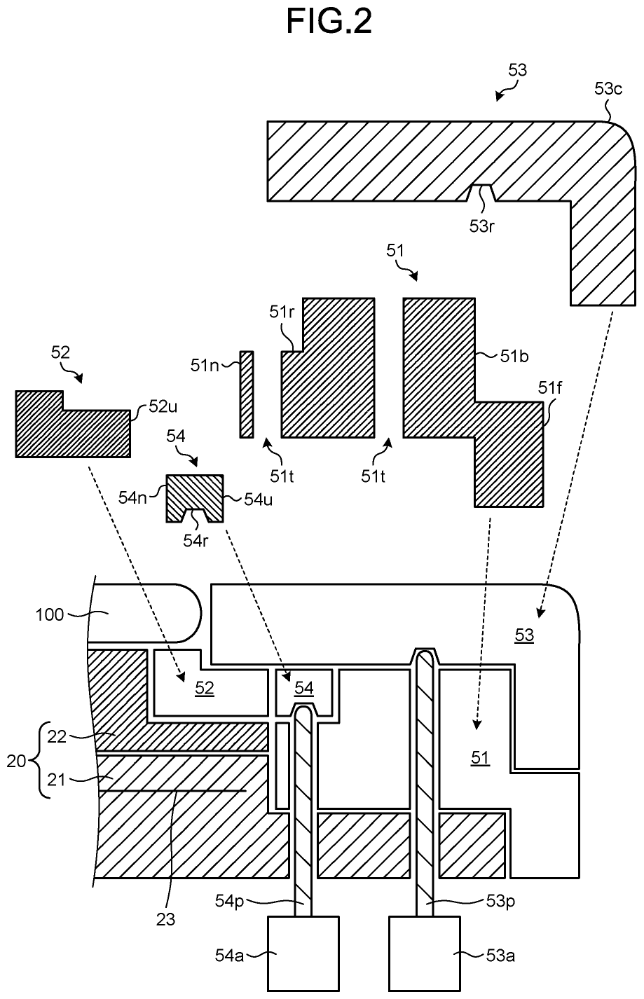

Next, with reference to FIG. 2, an explanation will be given of a specific configuration example of the edge ring 50 according to the embodiment. FIG. 2 is a sectional view on one side of the edge ring 50 according to the embodiment. FIG. 2 illustrates, at its lower left, a state where the edge ring 50 is set on the wafer stage 20.

As illustrated in FIG. 2, the lower ring 51 includes a main body 51b and a leg portion 51f extending downward from one end of the main body 51b. The main body 51b includes a recessed portion 51r as an upper portion on an inner wall surface 51n side. Through-holes 51t are formed in respective ones of the bottom surface of the recessed portion 51r and the upper surface of the main body 51b near the outer circumference.

The intermediate ring 52 has a cross section formed in an L-shape on one side of the ring shape. In other words, the intermediate ring 52 has a recessed shape of the upper surface on an outer wall surface 52u side.

The upper ring 53 also has a cross section formed in an L-shape on one side of the ring shape. The corner 53c of the L-shape facing the outer circumferential side of the upper ring 53 has a rounded shape. The upper ring 53 includes a recessed portion 53r on the lower surface positioned on the inner side of the L-shape.

The auxiliary ring 54 has a cross section formed in a rectangular shape on one side of the ring shape. Thus, the auxiliary ring 54 includes an inner wall surface 54n and an outer wall surface 54u that are set substantially in parallel with each other. The auxiliary ring 54 includes a recessed portion 54r on the lower surface.

The wafer stage 20 includes a base body 21 with a lower electrode 23 built therein, and a ceramic plate 22 for placing the wafer 100 thereon. Each of the base body 21 and the ceramic plate 22 includes a flange portion as a peripheral portion. The ceramic plate 22 is bonded to a mesa portion at the center of the base metal 21, so that the peripheral portion of wafer stage 20 is provided with three steps that become higher toward the central portion on which the wafer 100 is to be placed. In accordance with these steps, the respective members of the edge ring 50 described above are arranged.

The lower ring 51 is mounted on the flange portion of the base body 21 of the wafer stage 20. At this time, the lower surface of the main body 51b is set in contact with the flange portion of the base body 21, and the inner wall surface 51n is set opposed to the side surface of the mesa portion of the base body 21 and the side surface of the flange portion of the ceramic plate 22. Further, the leg portion 51f of the lower ring 51 is set to cover the side surface of the flange portion of the base body 21.

The intermediate ring 52 is mounted on the flange portion of the ceramic plate 22 of the wafer stage 20. At this time, the bottom surface of the L-shape of the intermediate ring 52 is set in contact with the flange portion of the ceramic plate 22, and the side surface of the L-shape is set opposed to the side surface of the mesa portion of the ceramic plate 22.

The auxiliary ring 54 is contained in the recessed portion 51r of the lower ring 51. At this time, the inner wall surface 54n of the auxiliary ring 54 is set opposed to the outer wall surface 52u of the intermediate ring 52, and the outer wall surface 54u of the auxiliary ring 54 is set opposed to the side surface of the recessed portion 51r of the lower ring 51.

The lower ring 51, the intermediate ring 52, and the auxiliary ring 54 are combined as described above, so that the upper surface of the intermediate ring 52 positioned on the inner side of the L-shape, the upper surface of the auxiliary ring 54, the upper surface of the main body 51b of the lower ring 51 are aligned at substantially the same height.

The upper ring 53 is mounted from above to cover entirely over these upper surfaces. At this time, the lower surface of the upper ring 53 is set in contact with the respective upper surfaces of the lower ring 51, the intermediate ring 52, and the auxiliary ring 54. Further, the inner wall surface of the L-shape of the upper ring 53 is set opposed to the outer wall surface of the main body 51b of the lower ring 51, and the lower end of the L-shape of the upper ring 53 is set in contact with the upper surface of the leg portion 51f of the lower ring 51. Further, the outer wall surface of the upper ring 53 extending downward and the outer wall surface of the leg portion 51f of the lower ring 51 form a substantially flat state without steps. In other words, the outer diameter of the upper ring 53 and the outer diameter of the leg portion 51f of the lower ring 51 are substantially equal to each other.

The respective pins 53p connected to the drive units 53a extend from below the wafer stage 20, penetrate the flange portion of the base body 21 of the wafer stage 20, pass through ones of the through-holes 51t of the lower ring 51, and come into contact with the recessed portion 53r on the lower surface of the upper ring 53. The respective pins 54p connected to the drive units 54a extend from below the wafer stage 20, penetrate the flange portion of the base body 21 of the wafer stage 20, pass through the others of the through-holes 51t of the lower ring 51, and come into contact with the recessed portion 54r on the lower surface of the auxiliary ring 54.

In a state where the wafer 100 is placed on the upper surface of the mesa portion of the ceramic plate 22, the lower surface of the wafer 100 is opposed to the upper end of the L-shape of the intermediate ring 52. The inner wall surface of the upper ring 53 is opposed to the end of the wafer 100, and the upper surface of the wafer 100 and the upper surface of the upper ring 53 are aligned at substantially the same height. Consequently, it is possible to suppress the plasma sheath distortion at the outer circumferential side of the wafer 100, and to cause ions in the plasma to be incident onto the wafer 100 substantially perpendicularly to the wafer 100.

The edge ring 50 is configured to combine plurality of members as described above to cover the peripheral portion of the wafer stage 20 substantially entirely. Consequently, it is possible to prevent the peripheral portion of the wafer stage 20 from being exposed to plasma and thereby worn out. Instead, the edge ring 50 is worn out by an amount corresponding to the above, but the edge ring 50 is composed of a plurality of members separable from each other. Thus, for example, only the upper ring 53, which is supposed to be worn out most severely, may be replaced as needed, and it is possible to reduce the frequency of replacement of the other members of the edge ring 50.

(Example of Use of Edge Ring)

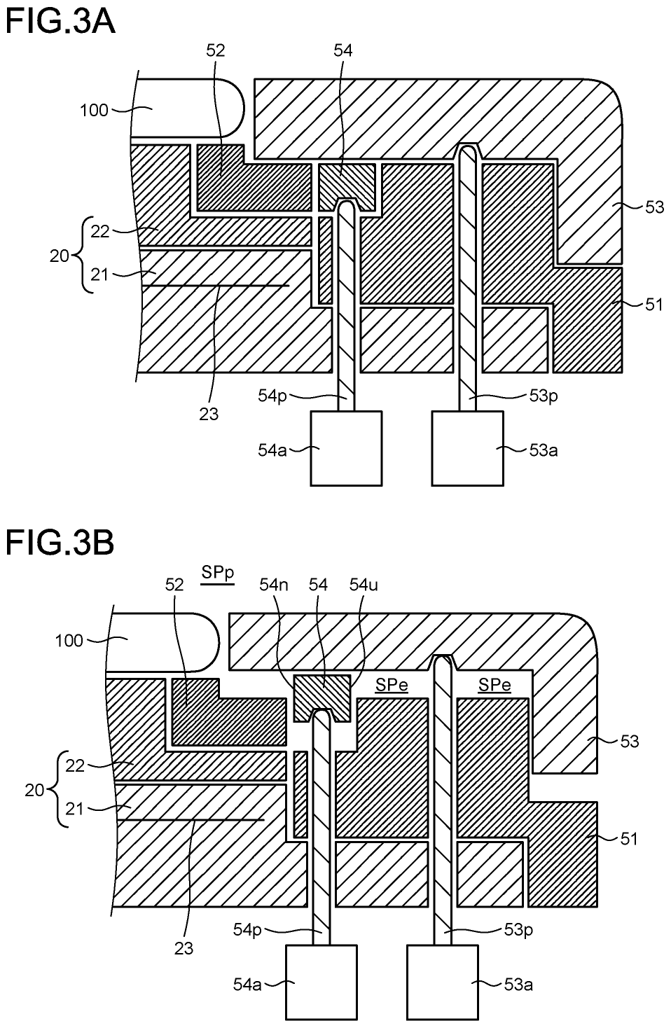

Next, with reference to FIGS. 3A and 3B, an explanation will be given of an example of use of the edge ring 50 according to the embodiment. FIGS. 3A and 3B are schematic views each illustrating a state where the edge ring 50 according to the embodiment is used in the plasma processing apparatus 1. FIG. 3A illustrates a state immediately after the edge ring 50 is installed. FIG. 3B illustrates a state after the edge ring 50 is used for a predetermined time.

As illustrated in FIG. 3A, immediately after the install, the upper ring 53 and the auxiliary ring 54 are present at lower positions. Specifically, the upper surface of the auxiliary ring 54 is present at substantially the same height position as the upper surface of the intermediate ring 52 and the upper surface of the lower ring 51. Further, the lower surface of the upper ring 53 is in contact with the upper surfaces of these members.

As illustrated in FIG. 3B, after the use for a predetermined time, the upper ring 53 has been worn out from the upper surface and become thinner. Accordingly, in order to align the upper surface of the upper ring 53 with the height position of the wafer 100, the upper ring 53 is pushed up by the drive units 53a and the pins 53p and is thereby moved to an upper position. At this time, a space SPe is created between the upper ring 53 and the lower ring 51.

Along with the upward movement of the upper ring 53, the auxiliary ring 54 is also pushed up by the drive units 54a and the pins 53p, and is moved to an upper position by an amount corresponding to the movement of the upper ring 53. The auxiliary ring 54 is moved upward by the same amount as the upper ring 53. In other words, the drive units 54a drive in synchronism with the drive units 53a. Consequently, the upper surface of the auxiliary ring 54 remains in contact with the lower surface of the upper ring 53.

Further, the auxiliary ring 54 partly projects from the recessed portion 51r of the lower ring 51, and thus an upper part of the outer wall surface 54u of the auxiliary ring 54 comes to face the space SPe between the upper ring 53 and the lower ring 51. Further, an upper part of the inner wall surface 54n of the auxiliary ring 54 comes to face a space SPp opened to the chamber 11 side. The space SPp also serves as a plasma generation space, and serves as a processing space for processing the wafer 100.

In other words, the space SPe between the upper ring 53 and the lower ring 51 and the space SPp on the chamber 11 side are isolated from each other by the auxiliary ring 54.

On the other hand, as the upper ring 53 is formed in a L-shape as described above, the space SPe between the upper ring 53 and the lower ring 51 and the space SPp on the chamber 11 side are isolated from each other also by the upper ring 53. In other words, the auxiliary ring 54 isolates the spaces SPe and SPp from each other on the inner circumferential side of the edge ring 50, while the upper ring 53 isolates the spaces SPe and SPp from each other on the outer circumferential side of the edge ring 50.

Thereafter, when the use time of the edge ring 50 is further extended and the upper surface of the upper ring 53 is further worn out, the upper ring 53 is further moved to an upper position in accordance with the height position of the upper surface of the wafer 100. The auxiliary ring 54 is also moved by an amount corresponding to the rise of the upper ring 53. Then, before the lower end of the auxiliary ring 54 exceeds the upper surfaces of the intermediate ring 52 and the lower ring 51, the upper ring 53 is replaced. In other words, the thickness of the auxiliary ring 54 has been set in accordance with the service life of the upper ring 53.

The rising positions of the upper ring 53 and the auxiliary ring 54 are controlled by data acquired in advance. Specifically, the wear amount of the upper ring 53 or the process characteristics of the wafer 100 processed at that time is acquired in advance in accordance with the use time of the edge ring 50. Then, on the basis of the acquired data, the rising positions of the upper ring 53 and the auxiliary ring 54 are determined, in correlation with each predetermined use time. Thereafter, in accordance with the use time, the rising positions of the upper ring 53 and the auxiliary ring 54 are adjusted, as needed.

Here, the upward driving of the upper ring 53 and the auxiliary ring 54 may be performed stepwise. For example, it is repeated that upper ring 53 and the auxiliary ring 54 are kept used for a predetermined period of time at respective predetermined positions set stationary and are then moved upward by a predetermined amount after a lapse of a predetermined use time.

### Comparative Example

In a plasma processing apparatus, members in the chamber are worn out by plasma. When an edge ring arranged around the wafer is worn out, the plasma sheath is distorted and thereby causes fluctuations of the process characteristics. In consideration of the above, in a plasma processing apparatus according to a comparative example, an edge ring is moved upward in accordance with the wearing degree of the edge ring.

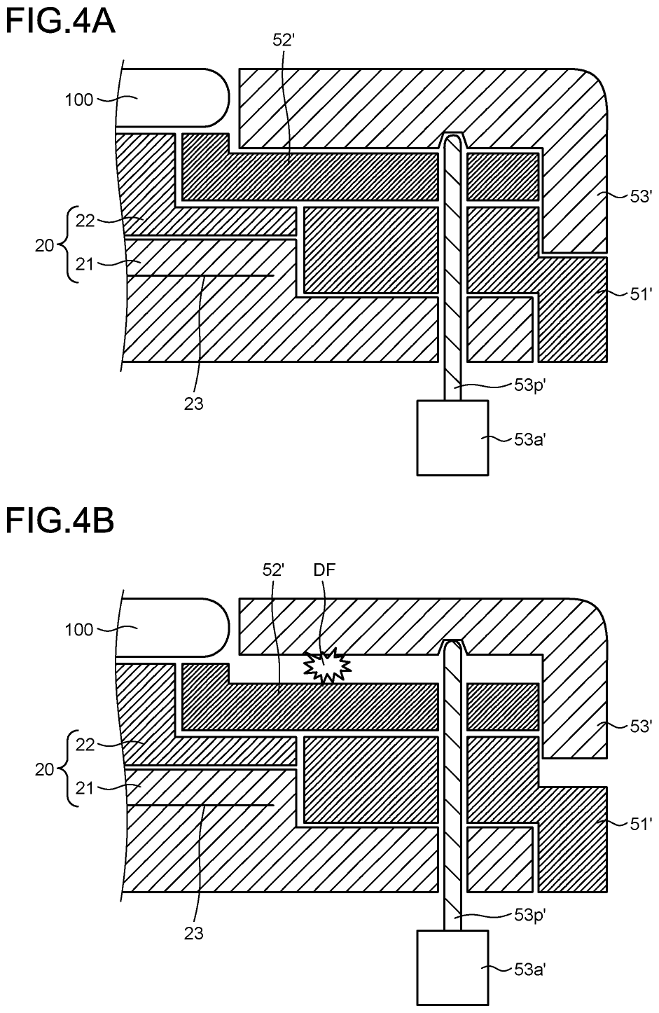

FIGS. 4A and 4B are schematic views each illustrating a state where an edge ring of a plasma processing apparatus according to a comparative example is used. As illustrated in FIG. 4A, the plasma processing apparatus according to the comparative example includes an edge ring that is composed of a lower ring 51′ arranged on the peripheral portion of the wafer stage, an intermediate ring 52′ on the lower ring 51′, and an upper ring 53′ on the intermediate ring 52′.

Pins 53p′ penetrate through the peripheral portion of the wafer stage, the lower ring 51′, and the intermediate ring 52′ and come into contact with the upper ring 53′. The pins 53p′ are driven up and down by drive units 53a′, by which the upper ring 53′ is pushed up to align the height of the upper surface of the upper ring 53′ with the height of the upper surface of the wafer 100.

As illustrated in FIG. 4B, after the use for a predetermined time, the upper ring 53′, which has been worn out and thinner, is pushed up by the pins 53p′ to maintain a state where the height of the upper surface of the upper ring 53′ is aligned with the height of the wafer 100. However, there is a case where a space is created between the upper ring 53′ and the intermediate ring 52′ and abnormal discharge DF due to plasma occurs in the space.

For example, the abnormal discharge may apply damage to semiconductor devices to be formed on the wafer 100, by becoming a cause of charge-up damage to the semiconductor devices, or by bringing about a source of particle generation. Consequently, the yield of the semiconductor devices is lowered.

In the plasma processing apparatus 1 according to the embodiment, the edge ring 50 includes the auxiliary ring 54, which is to be moved upward together with the upper ring 53 and is provided with the inner wall surface 54n facing the side to be opened to the inside of the chamber 11. With this arrangement, the auxiliary ring 54 isolates the space SPe between the upper ring 53 and the lower ring 51 and the space SPp on the chamber 11 side from each other. Thus, the abnormal discharge in the space SPe is suppressed. Consequently, it is possible to suppress the fluctuations of the process characteristics by moving the upper ring 53 upward and to improve the device yield by the shielding effect of the auxiliary ring 54.

In the plasma processing apparatus 1 according to the embodiment, the lower ring 51 includes the recessed portion 51r for containing the auxiliary ring 54. Consequently, when the upper ring 53 and the auxiliary ring 54 are present at the lower positions, the height of the upper surface of the auxiliary ring 54 can be aligned with the height of the upper surfaces of the lower ring 51 and the intermediate ring 52, so that the upper ring 53 can be mounted on these members.

In the plasma processing apparatus 1 according to the embodiment, the intermediate ring 52 is formed more compact as compared with the intermediate ring 52′ according to the comparative example, and is not interposed between the upper ring 53 and the lower ring 51. Further, the recessed portion 51r for containing the auxiliary ring 54 is located on the upper surface of the lower ring 51 on the inner wall surface 51n side. Thus, the auxiliary ring 54 can be arranged near the inner diameter side of the entire edge ring 50. Consequently, it is possible to enlarge the space SPe shielded by the auxiliary ring 54, and thereby to further reduce the probability of occurrence of abnormal discharge.

In the plasma processing apparatus 1 according to the embodiment, the thickness of the auxiliary ring 54 has been set in accordance with the service life of the upper ring 53. Consequently, it is possible to prevent the auxiliary ring 54 from entirely projecting from the recessed portion 51r of the lower ring 51 and thereby impairing the shielding effect of the auxiliary ring 54, before the replacement of the upper ring 53.

### Modification Example 1

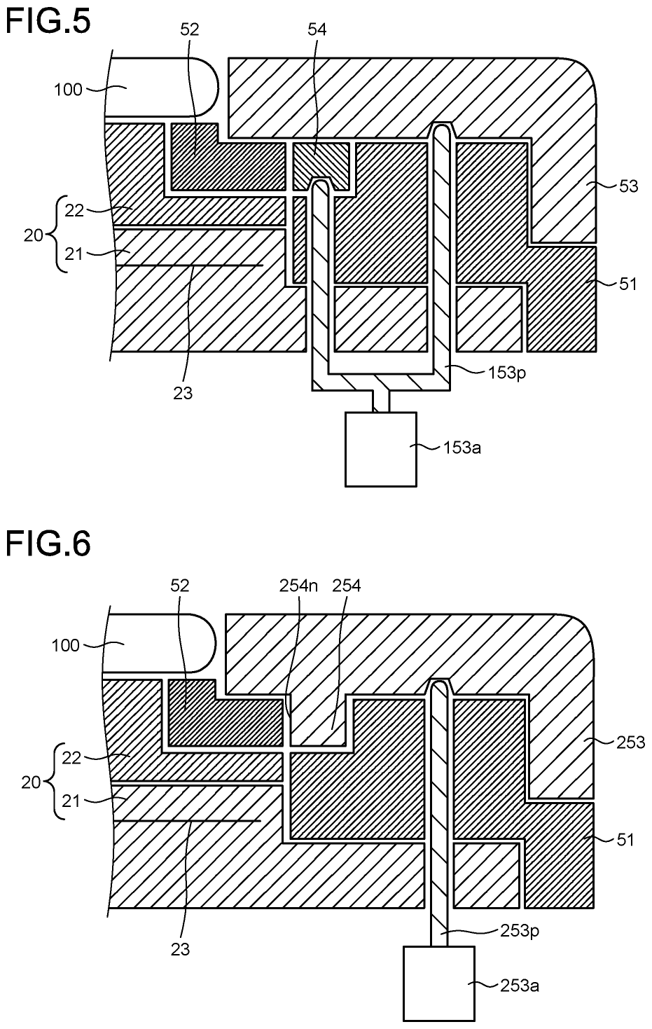

Next, with reference to FIG. 5, an explanation will be given of a plasma processing apparatus according to a modification 1 of the embodiment. The modification 1 differs from the embodiment described above, in that the number of drive units 153a is smaller. FIG. 5 is a schematic view illustrating a state where an edge ring 50 is used in a plasma processing apparatus according to the modification 1 of the embodiment.

As illustrated in FIG. 5, the edge ring 50 of the modification 1 has substantially the same configuration as the embodiment described above. However, at each of the locations for contact with both of the upper ring 53 and the auxiliary ring 54, one branching pin 153p, which forks into two portions, is provided to come into contact with these rings. Each of the pins 153p is connected to one drive unit 153a.

In the plasma processing apparatus according to the modification 1, a drive mechanism is formed mainly of three or more pins 153p and three or more drive units 153a corresponding to these pins.

In the plasma processing apparatus according to the modification 1, as the number of drive units 153a is smaller, it is possible reduce the cost of the plasma processing apparatus.

### Modification Example 2

Next, with reference to FIG. 6, an explanation will be given of a plasma processing apparatus according to a modification 2 of the embodiment. The modification 2 differs from the embodiment described above, in that an upper ring 253 is provided with an auxiliary projection 254. FIG. 6 is a schematic view illustrating a state where an edge ring is used in a plasma processing apparatus according to the modification 2 of the embodiment.

As illustrated in FIG. 6, the edge ring of the modification 2 includes the upper ring 253 provided with the auxiliary projection 254 in place of the auxiliary ring 54 of the embodiment described above. The auxiliary projection 254 extends from the lower surface of the upper ring 253 toward the recessed portion 51r of the lower ring 51. The auxiliary projection 254 includes an inner wall surface 254n, which faces the side to be opened to the inside of the chamber when the auxiliary projection 254 is present at an upper position.

In this way, the edge ring of the modification 2 includes the auxiliary projection 254, which is formed integrally with the upper ring 253 and has the same function as the auxiliary ring 54 of the embodiment described above. Further, the plasma processing apparatus according to the modification 2 includes pins 253p configured to push up the upper ring 253 and drive units 253a that drive the pins 253p to move the upper ring 253 up and down, as a drive mechanism.

In the plasma processing apparatus according to the modification 2, the drive mechanism is formed mainly of three or more pins 253p and three or more drive units 253a corresponding to these pins.

In the plasma processing apparatus according to the modification 2, the auxiliary projection 254 is formed integrally with the upper ring 253. Thus, the number of members of the edge ring is smaller. Further, the number of drive units 253a is also smaller. Consequently, it is possible reduce the cost of the plasma processing apparatus.

### Other Modification Examples

In each of the embodiment and the modifications 1 and 2 described above, the plasma processing apparatus is configured as an RIE apparatus; however, this is not limiting. The plasma processing apparatus may be an apparatus for performing a plasma process other than etching, such as a Chemical Dry Etching (CDE) apparatus, Chemical Vapor Deposition (CVD) apparatus, or asking apparatus.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A plasma processing apparatus comprising:
a processing container processing a substrate;
a power supply supplying an electric power into the processing container to generate plasma;
an upper electrode arranged inside the processing container;
a substrate mounting table including a lower electrode opposed to the upper electrode, and placing the substrate thereon;
an edge ring arranged at an outer peripheral portion of the substrate mounting table to surround an periphery of the substrate; and
a drive mechanism driving at least part of the edge ring up and down,
wherein the edge ring includes
a lower ring mounted on the outer peripheral portion of the substrate mounting table,
an upper ring mounted on the lower ring to be movable up and down by the drive mechanism, and
an auxiliary ring arranged at a lower surface of the upper ring to be movable up and down together with the upper ring, and including a surface facing a side to be opened to an inside of the processing container.

2. The plasma processing apparatus according to claim 1, wherein
the lower ring includes a recessed portion containing the auxiliary ring, and
the auxiliary ring is contained in the recessed portion when the upper ring is present at a lower position.

3. The plasma processing apparatus according to claim 1, wherein the auxiliary ring shields a space between the lower ring and the upper ring from a space on the processing container side when the upper ring is present at an upper position.

4. The plasma processing apparatus according to claim 3, wherein
the upper ring has a ring shape in which a cross section on an outer circumferential side is formed in an L-shape, and
when the upper ring is present at the upper position,
the auxiliary ring shields the space between the lower ring and the upper ring from the space on the processing container side, on an inner circumferential side of the edge ring,
while an L-shape portion of the upper ring shields the space between the lower ring and the upper ring from the space on the processing container side, on an outer circumferential side of the edge ring.

5. The plasma processing apparatus according to claim 1, wherein the drive mechanism includes
a first drive unit driving the upper ring up and down, and
a second drive unit driving the auxiliary ring up and down.

6. The plasma processing apparatus according to claim 5, wherein the first drive unit and the second drive unit drive the upper ring and the auxiliary ring in synchronism with each other.

7. The plasma processing apparatus according to claim 5, wherein the drive mechanism includes
a first pin that includes one end to come into contact with the upper ring and another end connected to the first drive unit, and
a second pin that includes one end to come into contact with the auxiliary ring and another end connected to the second drive unit.

8. The plasma processing apparatus according to claim 7, wherein the lower ring includes
a first through-hole through which the first pin penetrates, and
a second through-hole through which the second pin penetrates.

9. The plasma processing apparatus according to claim 7, wherein
the upper ring includes a first recessed portion at a portion for the first pin to come into contact with, and
the auxiliary ring includes a second recessed portion at a portion for the second pin to come into contact with.

10. The plasma processing apparatus according to claim 1, wherein the drive mechanism includes a drive unit driving the upper ring and the auxiliary ring up and down.

11. The plasma processing apparatus according to claim 10, wherein the drive mechanism includes a pin that includes one end forking into two portions to come into contact with the upper ring and the auxiliary ring and another end connected to the drive unit.

12. The plasma processing apparatus according to claim 11, wherein the lower ring includes a first through-hole and a second through-hole, through which the pin including the one end forking into two portions penetrates.

13. The plasma processing apparatus according to claim 11, wherein
the upper ring includes a first recessed portion at a portion for the pin to come into contact with, and
the auxiliary ring includes a second recessed portion at a portion for the pin to come into contact with.

14. The plasma processing apparatus according to claim 1, wherein the auxiliary ring is formed integrally with the upper ring.

15. The plasma processing apparatus according to claim 14, wherein the drive mechanism includes a drive unit driving the upper ring up and down.

16. The plasma processing apparatus according to claim 15, wherein the drive mechanism includes a pin that includes one end to come into contact with the upper ring and another end connected to the drive unit.

17. The plasma processing apparatus according to claim 16, wherein the lower ring includes a through-hole through which the pin penetrates.

18. The plasma processing apparatus according to claim 16, wherein the upper ring includes a recessed portion at a portion for the pin to come into contact with.

19. The plasma processing apparatus according to claim 1, wherein the edge ring includes an intermediate ring arranged between the outer peripheral portion of the substrate mounting table and the upper ring.

20. The plasma processing apparatus according to claim 19, wherein, when the upper ring is present at a lower position, the surface of the auxiliary ring is opposed to an outer wall surface of the intermediate ring, which faces an outer circumferential side.
